(19) United States
(12) Patent Application Publication
(10) Pub. No.: US 2005/0275464 A1
(43) Pub. Date: Dec. 15, 2005

(54) Transistor amplifying stage

(75) Inventors: Pietro Filoramo, Siracusa (IT); Alberto Cavallaro, Catania (IT)

Correspondence Address: SEED INTELLECTUAL PROPERTY LAW GROUP PLLC, 701 FIFTH AVENUE, SUITE 6300, SEATTLE, WA, 98104-7092, US

(73) Assignee: STMicroelectronics S.r.l., Agrate Brianza (IT)

(21) Appl. No.: 11/140,506

(22) Filed: May 27, 2005

(30) Foreign Application Priority Data
May 27, 2004 (EP) 04425383.9

(51) Int. Cl. H03F 3/45

(52) U.S. Cl. 330/261

(57) ABSTRACT

An amplifying stage having a first circuit positioned between a first and a second reference voltage and having a first transistor with a first non-drivable terminal connected with a current supply and a second transistor having a first non-drivable terminal connected with a second non-drivable terminal of the first transistor, and the current supply connected to the first reference voltage, and a second circuit connected to the first circuit and fed by a current proportional to the current supplied by the current supply. The second circuit has at least one input terminal and is connected to a load. The first circuit has a connection between the first transistor and a drivable terminal of the second transistor for adapting current that passes through the second transistor to be the same as current from the current supply and the voltage between the first transistor and ground is greater than a saturation voltage between non-drivable terminals of the first transistor.

### BACKGROUND OF THE INVENTION

1. Field of the Invention

The present invention pertains to amplifiers and, more particularly, to a transistor amplifying stage having a wide input volume range.

2. Description of the Related Art

Transistor amplifiers are generally known, and an amplifier of this type is shown in FIG. 1. This amplifier includes a MOS transistor pair M1, M2 in differential configuration that are fed by a bias current Ibias conveyed by means of a mirror made up of transistors M4, M3. The input signal is the differential signal Vi+ and Vi− applied to the gate terminals of the respective transistors M1 and M2; and the drain terminals of the transistors M1 and M2 are connected to a load (LOAD). This amplifier configuration has the disadvantage of a low volume range input. In fact, in order for the current mirror M3, M4 to operate correctly, the voltage has to be Vi>Vds−sat3+Vgs1 where Vds−sat3 is the saturation voltage of the transistor M3 and Vgs1 is the voltage between the gate and source terminals of the transistor M1. So as to lessen the term Vds−sat3+Vgs1 the transistors M1 and M2 can be dimensioned in a weak inversion region, that is in an under-threshold region, to make the voltage Vgs1 nearly the same as the threshold voltage Vth. With the MOS transistors of the latest generation, the threshold voltage is between 250 mV and 400 mV. To ensure good accuracy of the mirror M3, M4, the voltage Vds−sat3 has to be kept at sufficiently high values, that is between 200 mV and 350 mV. In this manner the amplifier can be used for input voltages that exceed 450 mV.

A known amplifier circuit that has a greater input dynamic is shown in FIG. 2. This amplifier includes, in relation to the amplifier of FIG. 1, another current mirror made by PMOS transistor M7, M8 and another PMOS transistor differential pair M5, M6 having the drain terminals connected with the load LOAD and the source terminals connected to the source terminal of the transistor M7. The input signals Vi+ and Vi− are connected to the gate terminals of the respective transistors M1, M5 and M2, M6. In this manner for any value of the common mode input signal Vi+, Vi− the amplifier of FIG. 2 works correctly. The main disadvantage lies in the discontinuity of the amplification gain due to the use of two different transconductances for the PMOS transistors M5, M6 and the NMOS transistors M1, M2; in fact it is generally known that the transconductance of the PMOS transistor is lower than the transconductance of the NMOS transistor and in addition an operating region of the circuit is present in which both the NMOS and PMOS transistors are active with a consequent significant increase of the overall transconductance. To these disadvantages are added the disadvantages of a greater occupation of the area in the silicon blank where the circuit will be implemented and the greater dissipation of current.

### BRIEF SUMMARY OF THE INVENTION

In view of the state of the technique described, the disclosed embodiments of the present invention provide an amplifier that presents a wide input volume range.

In accordance with the present invention, an amplifying stage is provided that includes a first circuit part and a second circuit part, the first circuit part positioned between a first and a second reference voltage, the first circuit part including at least a first transistor having a first non-drivable terminal connected with a current supply and at least a second transistor having a first non-drivable terminal connected with a second non-drivable terminal of the at least first transistor. The current supply is connected to the first reference voltage, the second circuit part is connected through the circuit to the first circuit part and is powered by a current proportional to the current supplied by the current supply. The second circuit part has at least one input terminal and is connected to a load. The first circuit part further includes connection of the first non-drivable terminal of the at least one first transistor with the drivable terminal of the at least a second transistor, the connection being suitable for causing the current passing through the at least a second transistor to be equal to the current supplied by the current supply, and a voltage between the first non-drivable terminal of the at least a first transistor and ground to be greater than a saturation voltage between the non-drivable terminals of the at least first transistor, and further that the same at least one input signal is applied on a drivable terminal of the at least a first transistor and to an input terminal of the second circuit part.

In accordance with another embodiment of the invention, an amplifying stage is provided that includes a first transistor configured to receive an input signal and to convey a supply current to a second transistor in response to the input signal, the second transistor coupled to a reference voltage, a third transistor configured to receive the input signal and coupled between a load and a fourth transistor having a control terminal coupled to a control terminal of the second transistor and the fourth transistor coupled to the reference voltage, and a connection between a first terminal of the first transistor and the control terminal of the second transistor.

In accordance with yet another embodiment of the invention, an amplifying stage is provided that includes a differential pair of transistors formed of first and second transistors configured to receive an input signal and to convey a supply current to a third transistor in response to the input signal, the third transistor coupled to a reference voltage, a second differential pair of transistors formed of fourth and fifth transistors configured to receive the input signal and coupled between a load and a sixth transistor having a control terminal coupled to a control terminal of the third transistor and coupled to a reference voltage, and a connection between a first node coupling a first and second transistor of the first differential pair to the control terminal of the third transistor.

In accordance with still yet another embodiment of the invention, an amplifying stage is provided that has a first transistor configured to receive an input signal and to convey a supply current to a second transistor in response to the input signal, the second transistor coupled to a reference voltage, a first differential pair of transistors comprising a third transistor and a fourth transistor coupled between a load and a fifth transistor, the differential pair configured to receive the input signal, the fifth transistor having a control terminal coupled to a control terminal of the second transistor and coupled to the reference voltage, and a connection between a first terminal of the first transistor and the control terminal of the second transistor.

### BRIEF DESCRIPTION OF THE SEVERAL VIEWS OF THE DRAWING(S)

The characteristics and the advantages of the disclosed embodiments of the present invention will appear evident from the following detailed description of an embodiment thereof, illustrated as non-limiting example in the enclosed drawings, in which:

FIG. 1 is a circuit diagram of a transistor amplifying stage of the type known;

FIG. 2 is another circuit diagram of a transistor amplifying stage according to the known art;

FIG. 3 is a circuit diagram of a transistor amplifying stage according to an embodiment of the present invention;

FIG. 4 is a circuit diagram of an implementation of the transistor amplifying stage of FIG. 3;

FIG. 5 is a diagram of the gain in decibels of the circuit of FIG. 4;

FIG. 6 is a diagram of selected currents of the circuit of FIG. 4.

FIG. 7 is a circuit diagram according to a variant of the embodiment of FIG. 3;

FIG. 8 is a circuit diagram according to another variant of the embodiment in FIG. 3;

FIG. 9 is a circuit diagram of an operational amplifier according to the invention.

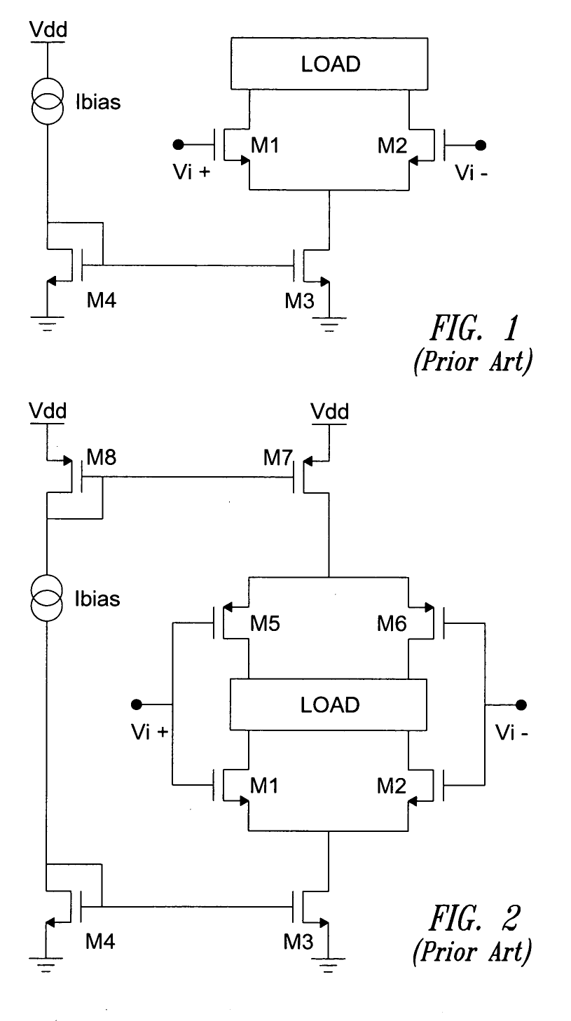

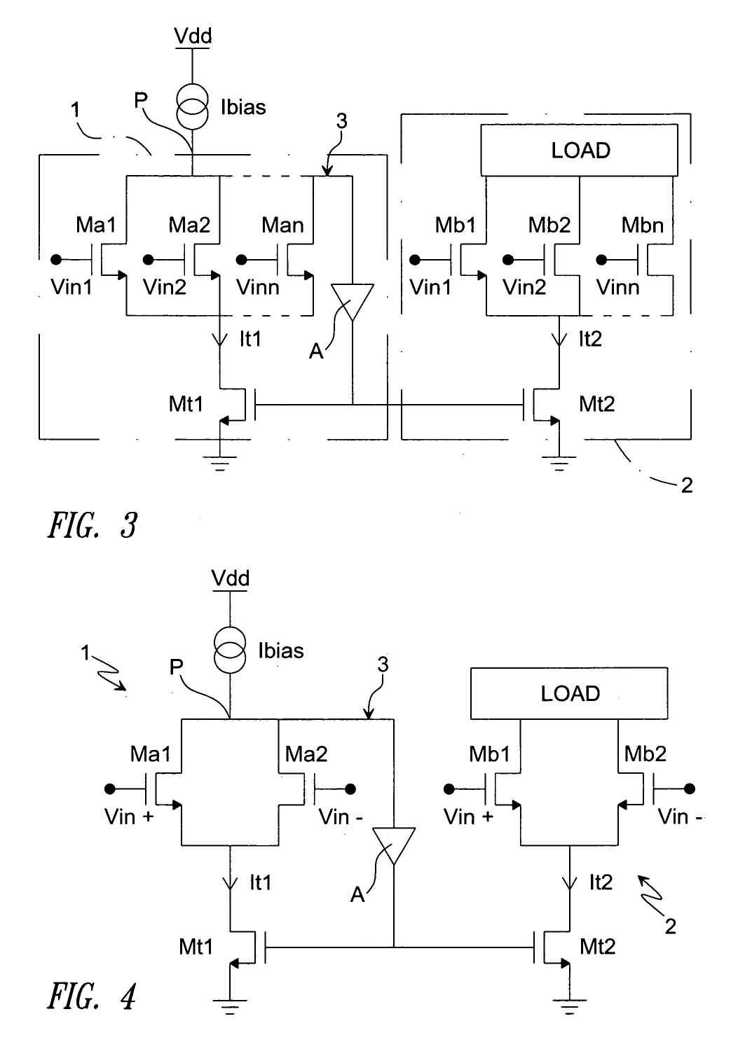

### DETAILED DESCRIPTION OF THE INVENTION

With reference to FIG. 3, a transistor amplifying stage formed in accordance with the present invention is shown, preferably formed of MOS transistors, has a first circuit part or master 1 and a second circuit part or slave 2. The first circuit part 1 includes at least one first transistor Ma1, which has a non-drivable terminal, in this case the drain terminal, connected with a current generator Ibias, and at least a second transistor Mt1 having a non-drivable terminal, in this case a drain terminal, connected with another non-drivable terminal, in this case a source terminal, of the at least one first transistor Ma1. Preferably the first circuit part 1 has a plurality of transistors Ma1 through Man having the drain and the source terminals in common. The current generator Ibias is connected to a supply voltage Vdd.

The second circuit part or slave 2 includes at least a third transistor Mt2 having a drivable terminal, in this case a gate terminal, connected with the drivable terminal (that is the gate terminal) of the second transistor Mt1 and at least a fourth transistor Mb1 having a non-drivable terminal, the source terminal, connected with a non-drivable terminal, the drain terminal, of the at least a third transistor Mt2 and another non-drivable terminal, the drain terminal, connected to a load LOAD. Preferably the at least a fourth transistor includes a plurality of transistors Mb1 through Mbn having the source and drain terminals in common. The gate terminals of the transistors Ma1 . . . Man and of the transistors Mb . . . . Mbn are connected to respective input signals Vin1 through Vinn.

The first circuit part 1 has a connection 3 of the drain terminal of the plurality of transistors Ma1 . . . Man with the gate terminal of the transistor Mt1. The connection 3 can consist of a simple electrical connection line or it can also include an amplifier A with high input impedance or with negligible input current. The connection is suitable for making the current It1 that passes through the transistor Mt1 the same as current supplied by the current generator Ibias. In fact the negative feedback, in the case in which the two currents are not equal and therefore the voltage on a node P tends to positive or negative supply, reacts by means of the connection 3 on the gate of the transistor Mt1 to restore the condition of equilibrium.

The connection A is suitable for making sure that the voltage between the drain terminal in common with the transistors Ma1 through Man and ground is greater than a saturation voltage Vds between the drain and the source terminals of the same transistors Ma1 . . . Man of at least a hundred-odd millivolts.

The first circuit part 1 presents three operating regions upon variation of the input voltage Vini in which one of the voltages from Vin1 to Vinn is indicated with Vini.

In the first operating region there is Vgs−ai<Vini<Va, where Vgs−ai is the voltage between the gate and source of the generic transistor Mai with i=1 . . . n and Va=Vgs−ai+Vds−sat-t1 where Vds−sat−t1, is the saturation voltage of the transistor Mt1. In the first region the transistor Mai operates in the saturation region and the transistor Mt1 operates in a triode region.

In the second operating region Va<Vini<Vb, where Vb indicates a voltage that depends on the circuit typology of the amplifier A. In the case in which the amplifier has a unitary gain or the drain terminal of the transistor Mai is directly connected to the gate terminal of the transistor Mt1, then Vb=Vgst1+Vth, where Vgst1 is the voltage between the gate terminals and the source of the transistor Mt1, and Vth is the threshold voltage of the generic MOS transistor. In the second operating region both the transistors Mai and Mt1 operate in saturation region.

In the third operating region Vini>Vb; in these conditions the transistor Mai operates in the triode region while the transistor Mt1 operates in the saturation region.

The second circuit part 2 is made in such a way that it is a scaled copy of the first circuit part 1 by means of a form factor γ that is the ratio between the form factors W/L of the transistor Mbi and of the transistor Mai (that is equal to the ratio between the form factors W/L of the transistor Mt2 and of the transistor Mt1). Therefore It2=γ*lbias where It2 is the drain current of the transistor Mt2. Therefore, the first circuit part 1 is made in such a way that it sets the input current to the second circuit part 2 and the latter represents the amplifying device of the whole circuit of FIG. 3.

The operation of the amplifier A is to raise the static precision. In fact the loop gain T of the first circuit part 1 is T=gt1×r×G where gt1 is the transconductance of the transistor Mt1, r is the overall dynamic resistance seen at the node P and G is the linear gain of the amplifier A.

FIG. 4 shows a circuit implementation of the apparatus described above with respect to FIG. 3 where only two transistors Ma1 and Ma2 are provided for the first circuit part 1 and only two transistors Mb1 and Mb2 for the second circuit part 2. The transistors Ma1, mb1 and Ma2, Mb2 have the respective input signals Vin+ and Vin−.

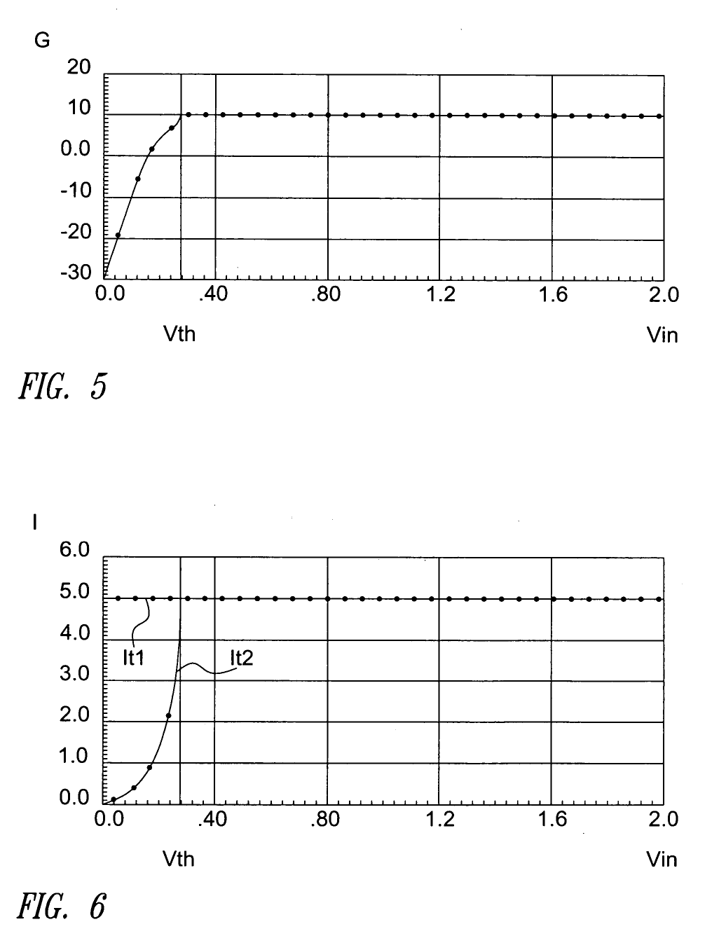

FIG. 5 shows the gain in decibels upon variation of the input voltage for the circuit of FIG. 4, assuming Vth=272 mV and assuming that the voltage Vgs−a1=Vgs−a2 is nearly the same as the voltage Vth. From the diagram of FIG. 5 it can be seen that the proposed amplifying stage has a wider input volume range than the known amplifying stages and it does not present discontinuity of gain.

FIG. 6 shows the path of the currents It1 and It2 upon variation of the input voltage for the circuit of FIG. 4.

An alternative to the use of only MOS transistors is that bipolar transistors can be used for the transistors Ma1 . . . Man and Mb1 . . . Mbn; and the transistors Mt1 and Mt2 remain MOS transistors.

The amplifying stage of FIG. 3 is particularly suitable for operating at low supply voltages, for example with Vdd=1V or Vdd=1,5V.

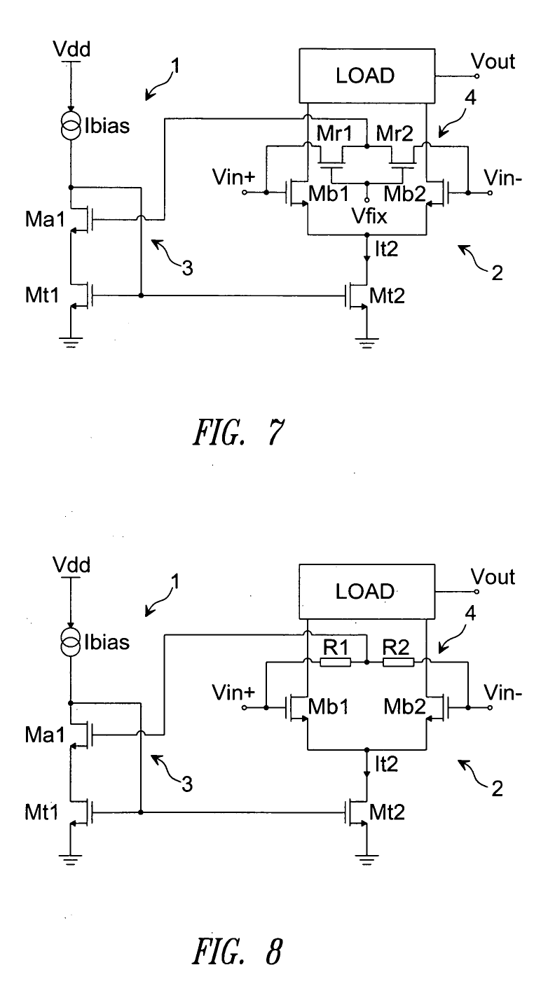

FIG. 7 shows a variant of the embodiment of the transistor amplifying stage in FIG. 3. Differently from the circuit in FIG. 3, the transistor amplifying stage in FIG. 7 has only a transistor Ma1 for the first circuit part 1 and only a differential transistor pair Mb1 and Mb2 for the second circuit part 2. The transistors Mb1 and Mb2 have the respective input signals Vin+ and Vin− at the input terminals. The gate terminal of the transistor Ma1 is connected with the output terminal of a common mode circuit 4 which is connected with the input terminals of the transistors Mb1 and Mb2 and is adapted to extract the common mode signal for driving the gate terminal of the transistor Ma1.

In FIG. 7 the common mode circuit 4 is formed by two triode transistors Mr1 and Mr2 which have the gate terminal in common and connected with a prefixed voltage Vfix, a non-drivable terminal in common, which represents the output terminal of the common mode circuit 4, while the other non-drivable terminal of the transistor Mr2 is connected with the input signal Vin− and with the gate terminal of the transistor Mb2, and the other non-drivable terminal of the transistor Mr1 is connected with the input signal Vin+ and with the gate terminal of the transistor Mb1. Therefore, in such a way the transistor Ma1 is driven by the output signal of the transistor Mr1-Mr2, which is a common mode signal. The transistors Mr1 and Mr2 can be two NMOS transistors or two PMOS transistors, and the voltage Vfix can be fixed at a value equal to Vdd or ground.

FIG. 8 shows another variant of the transistor amplifying stage in FIG. 3. The circuit in FIG. 8 is similar to the circuit in FIG. 7 and differs from it because in the place of the transistors Mr1 and Mr2 there are two resistances R1 and R2 respectively. One terminal of the resistance R2 is connected with the input signal Vin− and with the gate terminal of the transistor Mb2, one terminal of the resistance R1 is connected with the input signal Vin+ and with the gate terminal of the transistor Mb1, and the other terminals of the resistances R1 and R2 are in common and form the output terminal of this embodiment of the common mode circuit 4.

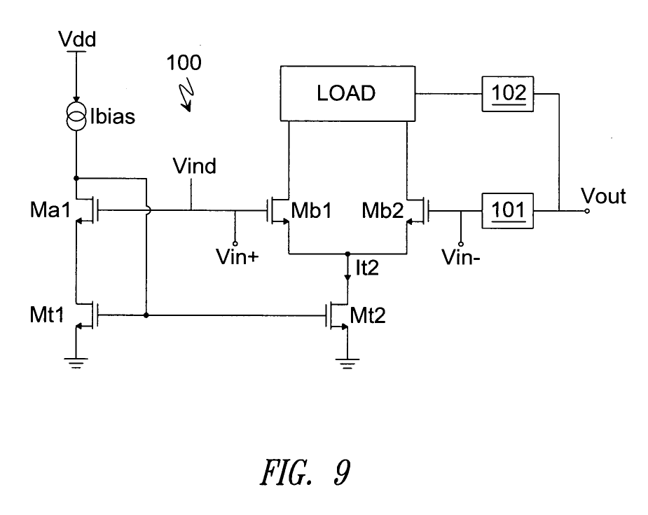

FIG. 9 shows a circuit diagram of an operational amplifier according to the invention. The operational amplifier includes an input stage 100 that includes a circuit diagram similar to the circuit diagram in FIG. 3. Differently from the circuit in FIG. 3, the input amplifying stage in FIG. 9 has only the transistor Ma1 for the first circuit part 1 and only two transistors Mb1 and Mb2 for the second circuit part 2. The transistor Mb1 has its gate terminal connected with the gate terminal of the transistor Ma1 and connected with a reference voltage Vind, for example a direct voltage, and the gate terminal of the transistor Mb2 is connected with a feedback network 101 that is connected with the output terminal of the output stage 102 of the operational amplifier. The output stage 102 is connected with the load LOAD and the gate terminals of the transistors Mb1 and Mb2 are connected with the input signals Vin+ and Vin−. This embodiment of the present invention is very effective if the gain of the operational amplifier is sufficiently high to assure virtual short-circuits between the inputs.

1. An amplifying stage, comprising a first circuit part and a second circuit part, said first circuit part disposed between a first and a second reference voltage, said first circuit part comprising at least a first transistor having a first non-drivable terminal connected with current supplying means and at least a second transistor having a first non-drivable terminal connected with a second non-drivable terminal of the at least a first transistor, said current supplying means connected to said first reference voltage, said second circuit part connected to said first circuit part and fed by a current proportional to the current supplied by said current supplying means, said second circuit part having at least one input terminal and being connected to a load, said first circuit part comprising means for connecting said first non-drivable terminal of the at least a first transistor with the drivable terminal of the at least a second transistor, said connection means adapting the current that passes through said at least a second transistor to be the same as current supplied by said current supplying means and the voltage between said first non-drivable terminal of the at least a first transistor and ground to be greater than the saturation voltage between the non-drivable terminals of said at least a first transistor, and at the drivable terminal of the at least a first transistor and at the at least one input terminal of the second circuit part the same at least one input signal is applied.

2. The amplifying stage of claim 1 wherein said second circuit part comprises at least another transistor having a drivable terminal connected with the drivable terminal of the at least a second transistor and at least a further transistor having a non-drivable terminal connected with a non-drivable terminal of the at least another transistor and another non-drivable terminal connected to a load.

3. The amplifying stage of claim 2 wherein said at least a first transistor is made up of a differential transistor pair having respectively a first and a second input signal and said at least one further transistor is made up of a differential transistor pair having respectively said first and said second input signal.

4. The amplifying stage of claim 1 wherein all of said transistors are MOS transistors.

5. The amplifying stage of claim 1 wherein said input signal is a radio-frequency signal.

6. The amplifying stage of claim 1 wherein said connection means comprise an electrical connection line.

7. The amplifying stage of claim 1 wherein said connection means comprise an amplifier having a high input impedance.

8. The amplifying stage of claim 1 wherein a value of said at least one input signal is greater than a voltage between the drivable terminal and said other non-drivable terminal of the first transistor.

9. The amplifying stage of claim 1 wherein said at least a first transistor comprises a plurality of transistors.

10. The amplifying stage of claim 3 wherein said at least one further transistor comprises a plurality of transistors.

11. The amplifying stage of claim 1 wherein said at least a second transistor has a second non-drivable terminal connected to ground.

12. The amplifying stage of claim 3 wherein said another transistor has another non-drivable terminal connected to ground.

13. The amplifying stage of claim 1 wherein a voltage between said non-drivable terminal of the at least a first transistor and ground is greater than at least a hundred-odd millivolts compared to a saturation voltage between the non-drivable terminals of said at least a first transistor.

14. An amplifying stage, comprising a first circuit part and a second circuit part, said first circuit part disposed between a first and a second reference voltage, said first circuit part comprising at least a first transistor having a first non-drivable terminal connected with current supplying means and at least a second transistor having a first non-drivable terminal connected with a second non-drivable terminal of the at least a first transistor, said current supplying means connected to said first reference voltage, said second circuit part connected to said first circuit part and fed by a current proportional to a current supplied by said current supplying means, said second circuit part comprising a differential transistor pair having input terminals connected respectively with a first input signal and with a second input signal, said differential transistor pair connected to a load, said first circuit part comprises means for connecting said first non-drivable terminal of the at least a first transistor with a drivable terminal of the at least a second transistor, said connection means configured to adapt current that passes through said at least a second transistor to be the same as current supplied by said current supplying means and a voltage between said first non-drivable terminal of the at least a first transistor and ground to be greater than a saturation voltage between the non-drivable terminals of said at least a first transistor, said amplifying stage further comprising means connected with a drivable terminal of the at least a first transistor of the first circuit part and with input terminals of the differential transistor pair for extracting a common mode signal for driving the drivable terminal of the at least a first transistor of the first circuit part.

15. The amplifying stage of claim 14 wherein said connection means comprises two transistors configured to operate in a triode region, said two transistors having a common drivable terminal connected with a reference voltage.

16. The amplifying stage of claim 15 wherein said two transistors of said connection means are MOS transistors.

17. The amplifying stage of claim 14 wherein said transistors are MOS transistors.

18. The amplifying stage of claim 14 wherein said connection means comprise an electrical connection line.

19. The amplifying stage of claim 14 wherein said connection means comprise an amplifier with high input impedance.

20. The amplifying stage of claim 14 wherein said second circuit part comprises at least another transistor having a drivable terminal connected with the drivable terminal of the at least a second transistor.

21. The amplifying stage of claim 14 wherein the value of an output signal of said means is greater than a voltage between the drivable terminal and said other non-drivable terminal of the at least a first transistor.

22. The amplifying stage of claim 20 wherein said at least a second transistor of said first circuit part has a second non-drivable terminal connected to ground and said another transistor of said second circuit part has another non-drivable terminal connected to ground.

23. The amplifying stage of claim 14 wherein a voltage between said non-drivable terminal of the at least a first transistor and ground is greater than at least a hundred-odd millivolts compared to a saturation voltage between the non-drivable terminals of said at least a first transistor.

24. An operational amplifier comprising an input stage, an output stage and a network circuit, said input stage comprising a first circuit part and a second circuit part, said first circuit part disposed between a first and a second reference voltage, said first circuit part comprising at least a first transistor having a first non-drivable terminal connected with current supplying means and at least a second transistor having a first non-drivable terminal connected with a second non-drivable terminal of the at least a first transistor, said current supplying means connected to said first reference voltage, said second circuit part connected to said first circuit part and fed by a current proportional to current supplied by said current supplying means, said second circuit part comprising a differential transistor pair having input terminals connected respectively with a first input signal and with a second input signal, a drivable terminal of said at least a first transistor connected with a drivable terminal of a transistor of said differential transistor pair, said differential transistor pair connected to a load, said first circuit part comprising means for connecting said first non-drivable terminal of the at least a first transistor with a drivable terminal of the at least a second transistor, said connection means configured to adapt current that passes through said at least a second transistor to be the same as current supplied by said current supplying means and the voltage between said first non-drivable terminal of the at least a first transistor and ground to be greater than a saturation voltage between the non-drivable terminals of said at least a first transistor, said drivable terminal of the at least a first transistor connected with a voltage reference and said amplifying stage having a gain sufficient for virtually short-circuiting its input terminals.

25. An amplifying stage, comprising:
a first transistor configured to receive an input signal and to convey a supply current to a second transistor in response to the input signal, the second transistor coupled to a reference voltage;
a third transistor configured to receive the input signal and coupled between a load and a fourth transistor, the fourth transistor having a control terminal coupled to a control terminal of the second transistor, and the fourth transistor coupled to the reference voltage; and
a connection between a first terminal of the first transistor and the control terminal of the second transistor.

26. The amplifying stage of claim 25 wherein the connection comprises a line.

27. The amplifying stage of claim 25 wherein the connection comprises an amplifier.

28. The amplifying stage of claim 25 wherein the connection is configured to adapt current that passes through the second transistor to be the same as the supply current.

29. The amplifying stage of claim 28 wherein the connection is further configured to adapt a voltage between the first terminal of the first transistor and the reference voltage to be greater than a saturation voltage between the first terminal and a second terminal of the first transistor.

30. The amplifying stage of claim 25, further comprising a plurality of transistors coupled in parallel with the first transistor.

31. The amplifying stage of claim 25, further comprising a plurality of transistors coupled in parallel with the third transistor.

32. The amplifying stage of claim 25, further comprising a plurality of transistors coupled in parallel with the first transistor and a plurality of transistors coupled in parallel with the third transistor.

33. The amplifying stage of claim 25, further comprising a current source coupled between a voltage supply and the first transistor.

34. An amplifying stage, comprising:
a differential pair of transistors comprising a first and second transistor configured to receive an input signal and to convey a supply current to a third transistor in response to the input signal, the third transistor coupled to a reference voltage;
a second differential pair of transistors comprising a fourth and fifth transistor configured to receive the input signal and coupled between a load and a sixth transistor having a control terminal coupled to a control terminal of the third transistor and coupled to a reference voltage; and
a connection between a first node coupling a first and second transistor of the first differential pair to the control terminal of the third transistor.

35. The amplifying stage of claim 34 wherein the connection comprises a line.

36. The amplifying stage of claim 34 wherein the connection comprises an amplifier.

37. The amplifying stage of claim 34 wherein the connection is configured to adapt current that passes through the third transistor to be the same as the supply current.

38. The amplifying stage of claim 37 wherein the connection is further configured to adapt a voltage between a first terminal of the first transistor and the reference voltage to be greater than a saturation voltage between the first terminal and a second terminal of the first transistor.

39. The amplifying stage of claim 34, further comprising a current source coupled between a voltage supply and the first differential pair of transistors.

40. An amplifying stage, comprising:
a first transistor configured to receive an input signal and to convey a supply current to a second transistor in response to the input signal, the second transistor coupled to a reference voltage;
a first differential pair of transistors comprising a third transistor and a fourth transistor coupled between a load and a fifth transistor, the differential pair configured to receive the input signal, the fifth transistor having a control terminal coupled to a control terminal of the second transistor and coupled to the reference voltage; and
a connection between a first terminal of the first transistor and the control terminal of the second transistor.

41. The amplifying stage of claim 40 wherein the connection comprises a line.

42. The amplifying stage of claim 40 wherein the connection comprises an amplifier.

43. The amplifying stage of claim 40 wherein the connection is configured to adapt current that passes through the second transistor to be the same as the supply current.

44. The amplifying stage of claim 43 wherein the connection is further configured to adapt a voltage between the first terminal of the first transistor and the reference voltage to be greater than a saturation voltage between the first terminal and a second terminal of the first transistor.

45. The amplifying stage of claim 40, further comprising a common mode circuit coupled between a control terminal of the third transistor and a control terminal of the fourth transistor, the common mode circuit having an output coupled to the control terminal of the first transistor.

46. The amplifying stage of claim 45 wherein the common mode circuit comprises first and second transistors coupled in series to each other at a second node that in turn is coupled to the control terminal of the first transistor.

47. The amplifying stage of claim 45 wherein the common mode circuit comprises first and second resistors coupled together in series at a second node that is coupled in to the control terminal of the first transistor.
